(19) United States
(12) Patent Application Publication
(10) Pub. No.: US 2011/0180136 A1
(43) Pub. Date: Jul. 28, 2011

(54) THIN FILM SOLAR CELL STRUCTURE AND METHOD OF PATTERNING ELECTRODE OF THE SAME

(75) Inventor: CHIH-HUNG HSIAO, TAICHUNG (TW)

(73) Assignee: NEXPOWER TECHNOLOGY CORP, Taichung City (TW)

(21) Appl. No.: 13/011,447

(22) Filed: Jan. 21, 2011

(30) Foreign Application Priority Data
Jan. 22, 2010 (TW) 099101843

(51) Int. Cl. H01L 31/0224; H01L 31/18

(52) U.S. Cl. 136/256; 438/98; 257/E31.124

(57) ABSTRACT

A thin film solar cell structure comprises a substrate, a front electrode layer, an absorber layer, and a back electrode layer stacked on one another sequentially. A first isolation groove goes through the back electrode layer and the absorber layer, and a second isolation groove is disposed concavely in the front electrode layer and filled with an insulative material. A conductive groove is disposed concavely in the absorber layer and filled with a conductive material. Therefore, the front electrode layer is electrically conducted to the back electrode layer via the conductive material. By means of a method of patterning the first isolation groove, second isolation groove and conductive groove, a succinct design of the thin film solar cell structure can be achieved.

### BACKGROUND OF THE INVENTION

1. Field of the Invention

The present invention relates to a thin film solar cell structure, and more particularly to a thin film solar cell structure and a method of patterning an electrode having an isolation groove and a conductive groove of the same.

2. Description of the Related Art

With reference to FIG. 1A for a conventional thin film solar cell, a thin film solar cell anode 91 is generally arranged on both sides of a thin film solar cell 90, and a cell cathode 92 is arranged at the middle of the thin film solar cell 90. Then, a conductive ribbon 93 (or conductive wire) is connected to the cell anode 91 and the cell cathode 92 for outputting electric power. However, this design reduces the response area of the thin film solar cell 90 in order to install the cell anode 91 and the cell cathode 92, so that the total output power of the thin film solar cell 90 is relatively lower.

With reference to FIGS. 1B and 1C for a design of a conventional thin film solar cell 90, the conductive ribbon 93 is usually coupled to the cell anode 91 or the cell cathode 92 by a soldering process. To allow a front electrode layer 14 to be electrically coupled to the conductive ribbon 93, solder points 921 of the cell anode 91 and the conductive ribbon 93 must be penetrated through a back electrode layer 16 and an absorber layer, such that the electric power of the front electrode layer 14 is outputted through the conductive ribbon 93, and the cell cathode 92 is fixed to the conductive ribbon 93 through the solder point 921. Therefore, the manufacturing process of the thin film solar cell 90 requires an additional process of soldering the conductive ribbon 93 and thus increases the manufacturing time of the thin film solar cell 90. For example, R.O.C. Pat. No. 200618324 discloses a method of soldering the electrodes with the conductive ribbon to constitute an electric connection to prevent a solar cell from being broken down or damaged by thermal stress or other factors. However, leads and solder points may be broken or peeled off easily, so that the manufacturing process further increases the material cost of the conductive ribbon and solder. R.O.C. Pat. No. M370833 (or Publication No. 98.12.14) discloses a solar cell having a circular groove formed by laser engraving and cutting, and removing the back electrode layer, absorber layer and front electrode layer to achieve the isolation and insulation effects. R.O.C. Pat. No. 200847457 discloses a method of engraving a plurality of cell anodes 91 and cell cathodes 92 from lateral sides of the thin film solar cell 90 in the laser engraving and cutting process, and each pair of the cell anodes 91 and cell cathodes 92 patterned on lateral sides of the thin film solar cell 90 are connected in series to constitute an electric connection. Although this method can reduce the number of laser engraving and cutting, metal conductive wires are used for serially connecting each pair of the cell anodes 91 and cell cathodes 92, and thus the manufacture still requires a complicated manufacturing procedure and a long manufacturing time.

With reference to FIG. 2 for a conventional method of patterning electrodes of a thin film solar cell 90, each cell is formed by connecting seven conductive ribbons 93 including five terminal ribbon 931 and two international ribbon 932, and this method consumes much material and still requires improvements to lower the cost and promote the extensive application of solar energy.

In view of the aforementioned problems, the industry has immediate demands for a novel thin film solar cell to overcome the problems of the prior art.

### SUMMARY OF THE INVENTION

Therefore, it is a primary objective of the present invention to overcome the aforementioned shortcomings of the prior art by providing a thin film solar cell structure and a method of patterning electrodes of the thin film solar cell structure.

To achieve the foregoing objective, the present invention provides a single-deck or multi-deck thin film solar cell structure, and the thin film solar cell comprises a panel electrode formed by a cell anode and a cell cathode. A conductive channel of the cell anode and the cell cathode is formed by patterning a first isolation groove, a second isolation groove and a conductive groove. The thin film solar cell further comprises a substrate, a front electrode layer, an absorber layer and a back electrode layer stacked sequentially on one another. Wherein, the first isolation groove is penetrated through the back electrode layer and the absorber layer. The second isolation groove is concavely formed on the front electrode layer and filled with an insulative material. The conductive groove is concavely formed on the absorber layer and filled with a conductive material. With the insulative material of the second isolation groove, a portion of the front electrode layer is electrically isolated by the second isolation groove. With the conductive material of the conductive groove, an electric connection between the front electrode layer and the back electrode layer is achieved to define the conductive channel between the electrodes of the thin film solar cell.

The present invention further provides a method of patterning electrodes of a single-deck or multi-deck thin film solar cell, and the method comprises the steps of:

S1: forming a front electrode layer on a surface of a substrate;

S2: patterning the front electrode layer to form a second isolation groove, filling an insulative material into the second isolation groove, forming one or more absorber layers on a surface of the front electrode layer, wherein the insulative material filled into the second isolation groove is the same material for making the absorber layer coupled to the front electrode layer, and while the absorber layer is being formed on the surface of the front electrode layer, the insulative material is filled into second isolation groove at the same time;

S3: patterning the absorber layer or each of the absorber layers to form a conductive groove, and filling a conductive material into the conductive groove;

S4: forming a back electrode layer on the uppermost surface of the absorber layer to produce a thin film solar cell panel; and

S5: patterning the back electrode and the absorber layer on the thin film solar cell panel to the front electrode layer to form a first isolation groove.

Therefore, the present invention provides a thin film solar cell structure having the back electrode layer and the absorber layer penetrated through the first isolation groove, the second isolation groove concavely formed on the front electrode layer and filled with an insulative material, and the absorber layer. Wherein, the conductive groove is concavely formed on the absorber layer and filled with a conductive material to produce a conductive channel of the thin film solar cell, so that current is collected from the cell cathode to the cell anode, and no conductive ribbon is required for outputting the electric power of the cell anode and the cell cathode.

Another objective of the present invention is to provide a thin film solar cell structure without requiring the design of a conductive ribbon, such that the response area of the thin film solar cell can be expanded to increase the total output of electric power of the thin film solar cell.

A further objective of the present invention is to provide a thin film solar cell structure without requiring a soldering of conductive ribbon, such that the manufacturing procedure of the thin film solar cell can be simplified and the material cost of the conductive ribbon can be saved.

### BRIEF DESCRIPTION OF THE DRAWINGS

FIG. 1A is a schematic view of connecting electrodes of a conventional thin film solar cell;

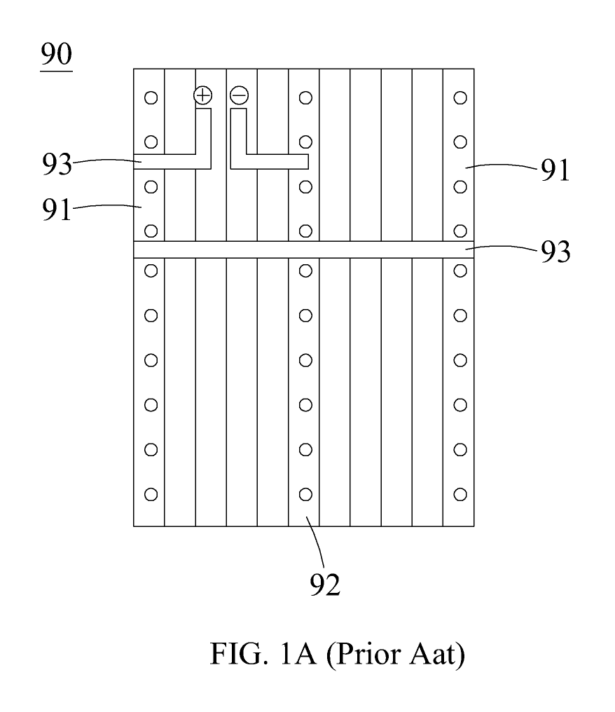

FIG. 1B is a cross-sectional view of an anode of a conventional thin film solar cell;

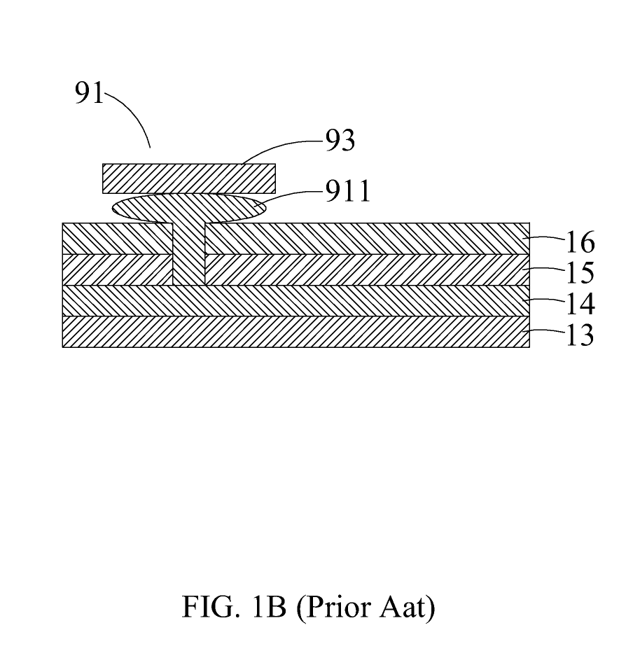

FIG. 1C is a cross-sectional view of a cathode of a conventional thin film solar cell;

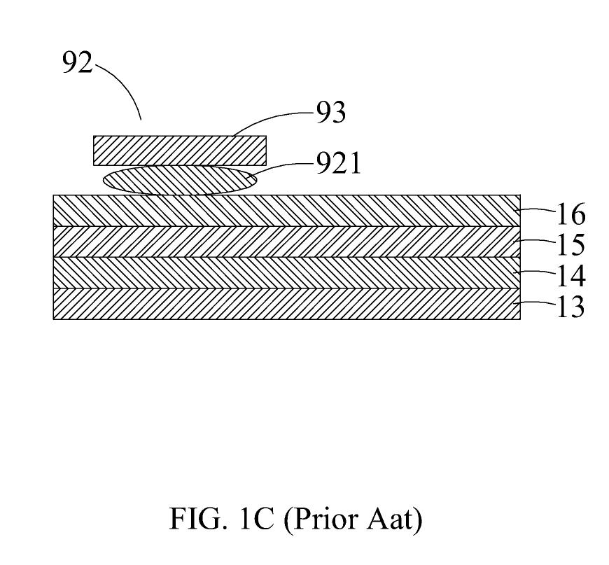

FIG. 2 is a schematic view of connecting a conductive ribbon of a conventional thin film solar cell with a cable junction box;

FIG. 3A is a schematic view of a thin film solar cell structure of the present invention;

FIG. 3B is a cross-sectional view of the thin film solar cell as depicted in FIG. 3A;

FIG. 3C is a cross-sectional view of a first isolation groove of the thin film solar cell as depicted in FIG. 3A;

FIG. 3D is a cross-sectional view of a second isolation groove of the thin film solar cell as depicted in FIG. 3A;

FIG. 3E is a cross-sectional view of a non-electrically isolated area of the thin film solar cell as depicted in FIG. 3A;

FIG. 4 is a schematic view of another way of connecting a thin film solar cell of the present invention with a cable junction box;

FIG. 5A is a cross-sectional view of a conductive groove of a double-deck front electrode layer of a thin film solar cell in accordance with the present invention;

FIG. 5B is a cross-sectional view of a first isolation groove of the double-deck front electrode layer of the thin film solar cell in accordance with the present invention;

FIG. 5C is a cross-sectional view of a second isolation groove of the double-deck front electrode layer of the thin film solar cell in accordance with the present invention;

FIG. 5D is a cross-sectional view of a non-electrically isolated area of the double-deck front electrode layer of the thin film solar cell in accordance with the present invention;

FIG. 5E is a schematic view of a path of passing a current of the double-deck front electrode layer of the thin film solar cell from a cell cathode to a cell anode of the solar cell in accordance with the present invention; and

FIG. 6 is a flow chart of a method of patterning electrodes of a thin film solar cell of the present invention.

### DETAILED DESCRIPTION OF THE PREFERRED EMBODIMENTS

The foregoing and other objectives, characteristics and advantages of the present invention will become apparent by the detailed description of a preferred embodiment as follows. It is noteworthy to point out that the present invention discloses a thin film solar cell structure and a method of patterning electrodes of the thin film solar cell. Wherein, the basic principle of etching ditches or grooves is adopted, and this principle is a prior art and thus will not be described here. In addition, the drawings are provided for the purpose of illustrating the technical characteristics of the present invention, but not intended for limiting the scope of the present invention.

In a thin film solar cell, a single chip has a power supply of approximately 0.6 watt, and such electric power is insufficient for the use of load voltage for a plurality of application modules, so that the present technology increases the current and electric power by connecting a plurality of thin film solar cell in series or in parallel. A general thin film solar cell is processed by a laser or mechanical patterning process to achieve the effect of connecting the thin film solar cells in series.

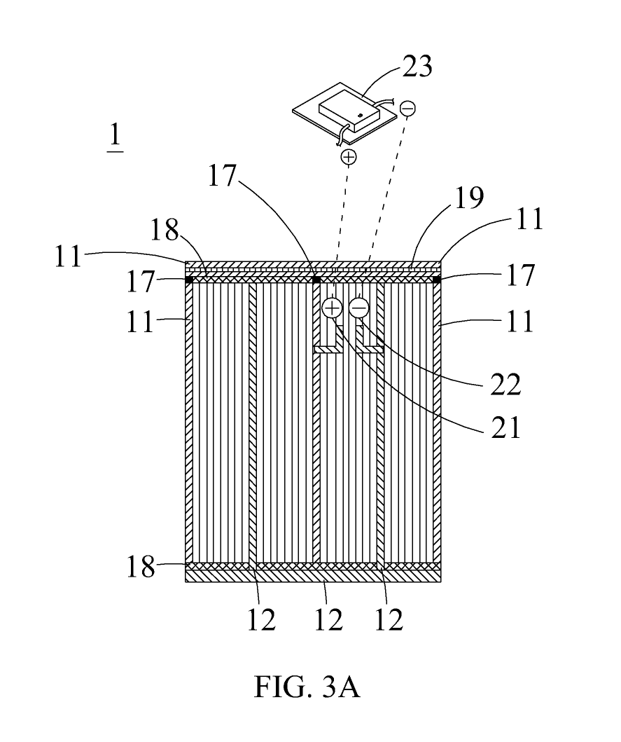

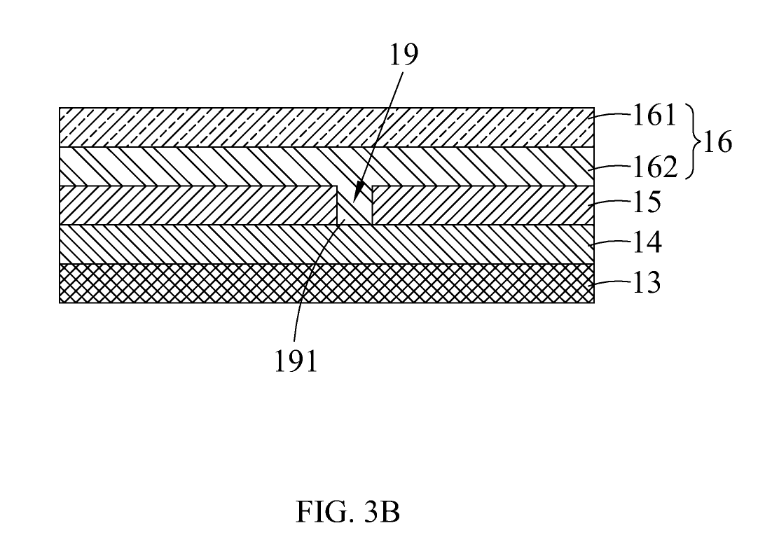

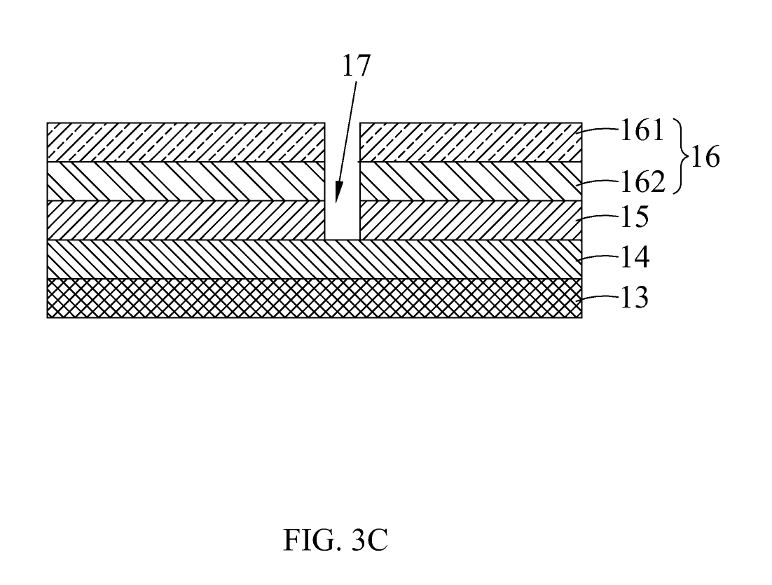

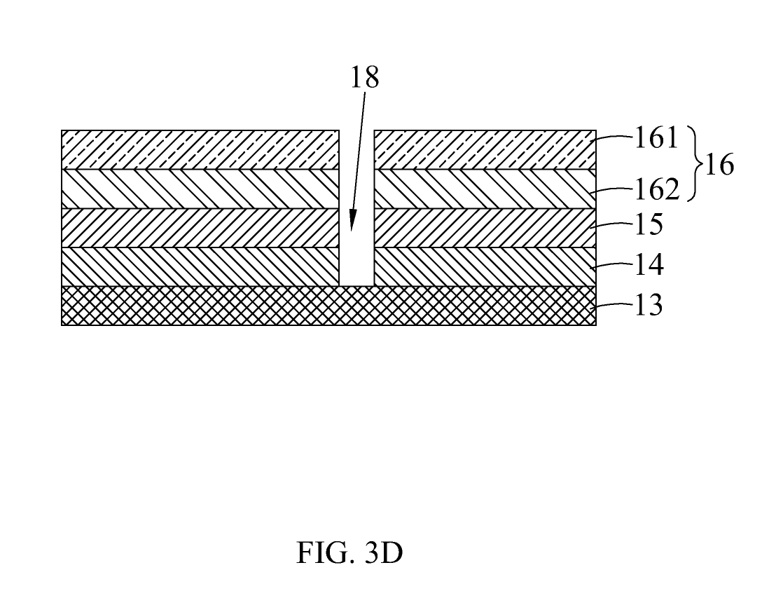

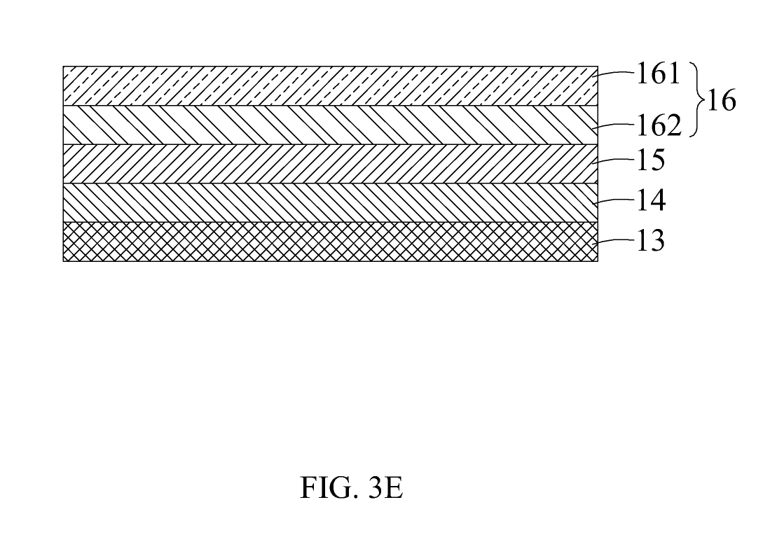

With reference to FIG. 3A for a schematic view of a thin film solar cell 1 in accordance with a preferred embodiment of the present invention, the thin film solar cell 1 includes a panel electrode comprised of a cell anode 11 and a cell cathode 12. The panel electrode of the thin film solar cell 1 is formed by patterning and electrically isolating a first isolation groove 17 and a second isolation groove 18. In FIG. 3A, the cell anode 11 is installed transversally at an end of the thin film solar cell 1, and the cell cathode 12 is installed longitudinally at the center of the thin film solar cell 1, and the cell anode 11 and the cell cathode 12 are perpendicular to each other. However, the positions of the cell anode 11 and cell cathode 12 can be adjusted according to the design requirements of the thin film solar cell 1, and a preferred embodiment is provided for illustrating the present invention, but the invention is not limited to such arrangement only.

With reference to FIGS. 3B˜3E, FIG. 3A shows a cross-sectional view of a thin film solar cell 1 comprising a substrate 13, a front electrode layer 14, an absorber layer 15 and a back electrode layer 16 stacked on one another sequentially. The cell anode 11 is installed at an end of the thin film solar cell 1, and the cell cathode 12 is installed at the other end of the thin film solar cell 1 and opposite to the cell anode 11. The first isolation groove 17 is formed at a position proximate to the cell anode 11 for isolating the electric conduction of the cell anode 11. In FIG. 3C, the first isolation groove 17 cuts the thin film solar cell 1 and penetrates through the back electrode layer 16 and the absorber layer 15 to isolate the electric conduction of the absorber layer 15. In FIG. 3B, the conductive groove 19 is concavely formed on the absorber layer 15 and filled with a conductive material 191. With the conductive material 191 of the conductive groove 19, an electric conduction between the front electrode layer 14 and the back electrode layer 16 can be achieved. The conductive material 191 is one selected from the collection of tin dioxide (Sn0₂), indium tin oxide (ITO), zinc oxide (ZnO), aluminum zinc oxide (AZO), gallium zinc oxide (GZO) and indium zinc oxide (IZO), and the substrate 13 is made of a transparent material. The front electrode layer 14 is made of a transparent conductive oxide (TCO) selected from the collection of tin dioxide (Sn02), indium tin oxide (ITO), zinc oxide (ZnO), aluminum zinc oxide (AZO), gallium zinc oxide (GZO) and indium zinc oxide (IZO). The absorber layer 15 is a single-layer structure or a multi-layer structure made of a material selected from the collection of a crystalline silicon semiconductor, an amorphous silicon semiconductor, a semiconductor compound, an organic semiconductor and a sensitized dye. The back electrode layer 16 is also a single-layer structure or a multi-layer structure, and further comprises a metal layer 161 and a conductive oxide layer 162. Wherein, the metal layer 161 is made of a metal selected from the collection of silver (Ag), aluminum (Al), chromium (Cr), titanium (Ti), nickel (Ni) and gold (Au), and the conductive oxide layer 162 is made of a material selected from the collection of tin dioxide (Sn02), indium tin oxide (ITO), zinc oxide (ZnO), aluminum zinc oxide (AZO), gallium zinc oxide (GZO) and indium zinc oxide (IZO). The cutting method includes but not limited to an etch cutting method, a laser cutting method or a mechanical cutting method.

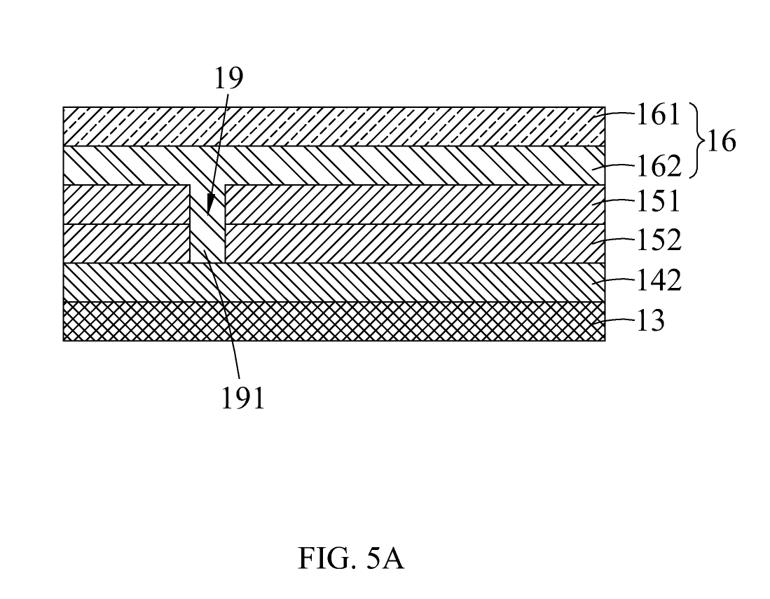

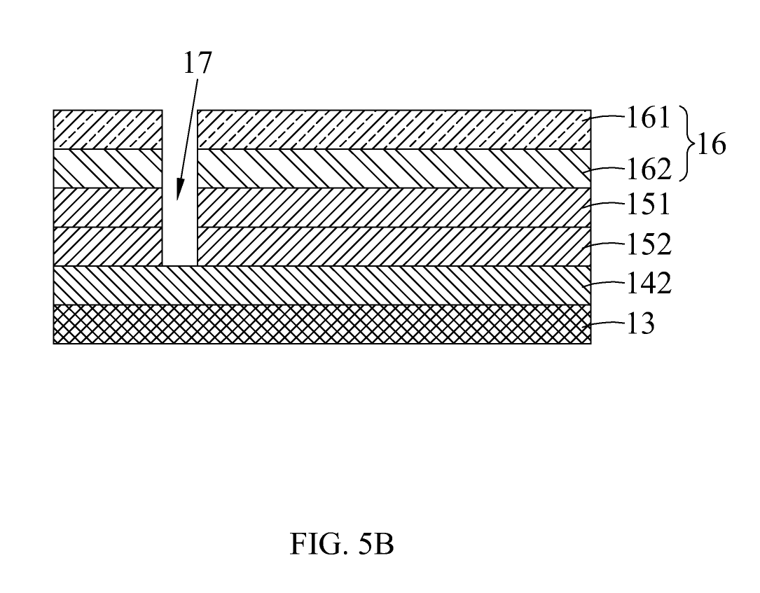

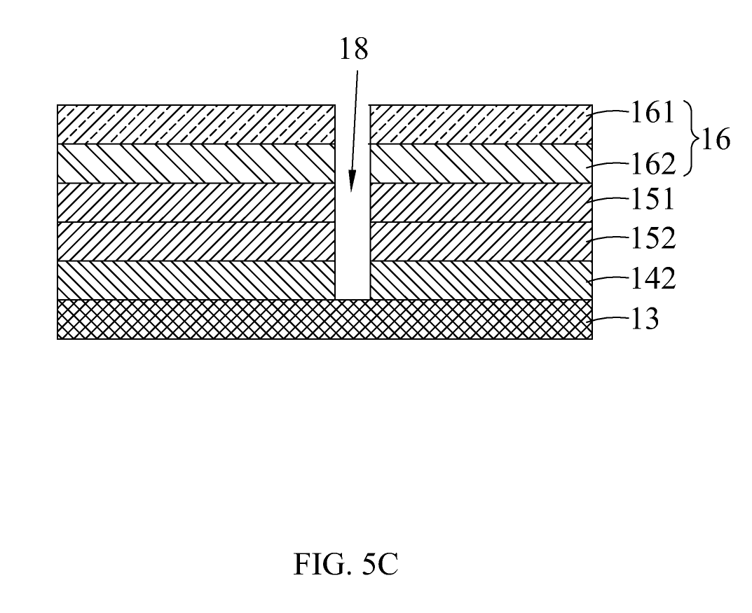

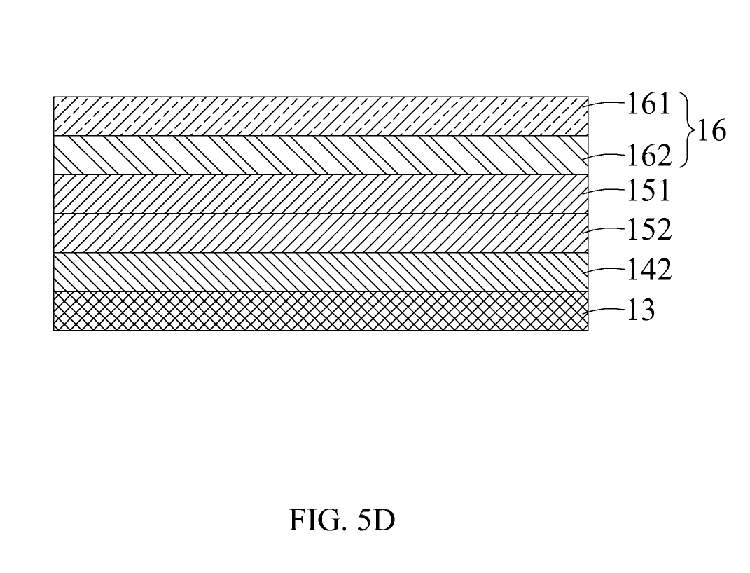

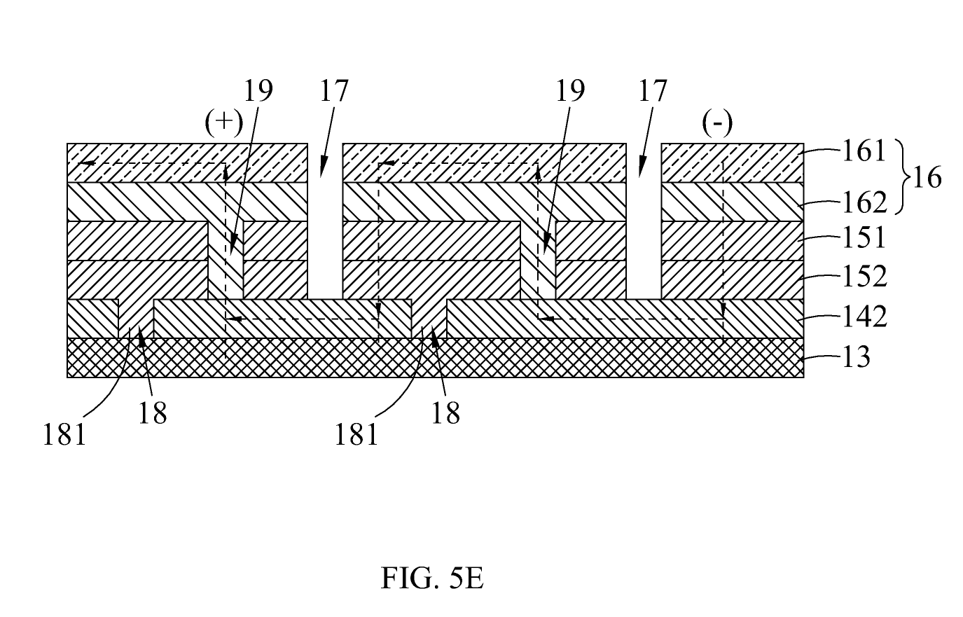

With reference to FIGS. 3A and 3D, FIG. 3D shows a cross-sectional view of the second isolation groove 18 as depicted in FIG. 3A. The second isolation groove 18 and the first isolation groove 17 are arranged transversally adjacent to each other, and the second isolation groove 18 is concavely formed on the front electrode layer 14 and filled with an insulative material 181. With the insulative material 181 of the second isolation groove 18, the front electrode layer 14 is electrically isolated by the second isolation groove 18. With the first isolation groove 17 and second isolation groove 18, the current generated by the cell cathode 12 can be transmitted from the front electrode layer 14 below the first isolation groove 17 only. With the conductive groove 19, the current is transmitted to the back electrode layer 16, and then to the cell anode 11. Wherein, the current is passed in a way as shown in FIG. 5E, except that FIG. 5E shows the structure of a multi-layer thin film solar cell 1. The way of passing the current is the same in both single-layer and multi-layer structures. Therefore, the current is collected from the cell anode 11, and the cell anode 11 can be connected in series without requiring the soldering of a conductive ribbon. For the non-electrically isolated area, the back electrode layer 16 or the metal layer 161 of the back electrode layer 16 can be used for the electric conduction as shown in FIG. 3E.

In this preferred embodiment, the first isolation groove 17, second isolation groove 18 and conductive groove 19 can be formed by an etch, laser, or mechanical cutting method, but the invention is not limited to such arrangements only. The positions of the first isolation groove 17, second isolation groove 18 and conductive groove 19 can be designed according to the actual conditions of patterning and serially connecting the thin film solar cell 1 and the required positions of the cell anode 11 and the cell cathode 12, and the conductive path of the current.

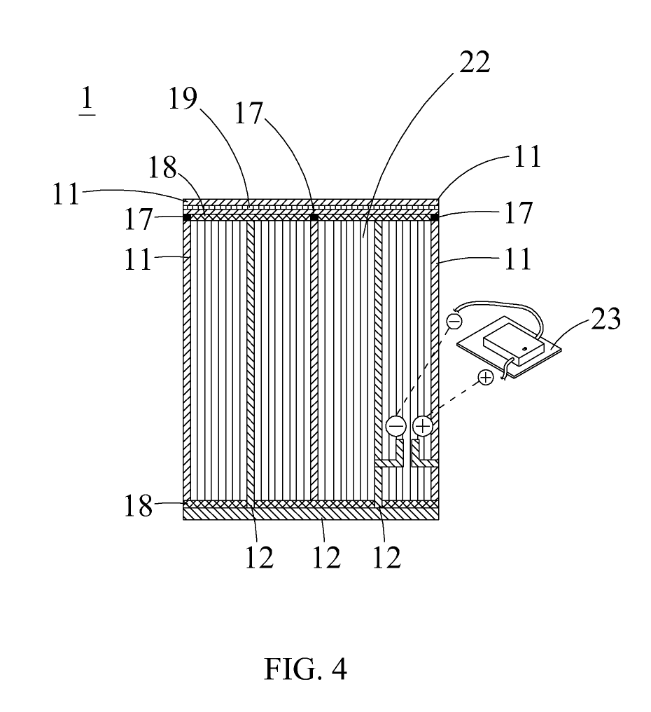

With reference to FIG. 4 for a schematic view of transmitting electric power generated by the thin film solar cell 1 to the outside, an anode terminal 21 is installed in a channel of the cell anode 11 and at an appropriate position of a cable junction box 23, and a cathode terminal 22 is installed on a channel of the cell cathode 12 and at an appropriate position of the cable junction box 23. In FIG. 4, the cell anode 11 and the cathode terminal 22 are installed at a position proximate to the center of the thin film solar cell 1 or installed at a position proximate to a lateral edge of the thin film solar cell 1, but the invention is not limited to such arrangements only. The anode terminal 21 and the cell anode 11 as well as the cathode terminal 22 and the cell cathode 12 are connected by a soldering method or a silver paste adhesion, but the invention is not limited to such arrangements. The power supply circuit of the thin film solar cell 1 can be connected to the anode terminal 21 and the cathode terminal 22 by a cable junction box 23 to allow the thin film solar cell 1 to supply electric power to the outside.

With reference to FIGS. 5A, 5B, 5C and 5D for a multi-layer thin film solar cell 1, a structure of a two-layer thin film solar cell 1 is shown. In FIG. 5A, a power generating layer at the top is an absorber layer 151, and a power generating layer at the bottom is formed by an absorber layer 152 and a front electrode layer 142. In FIG. 5A, a conductive groove 19 is concavely formed on the absorber layer 151 and the absorber layer 152 and filled with a conductive material 191. With the conductive material 191 of the conductive groove 19, an electric conduction between the front electrode layer 142 and the back electrode layer 16 can be achieved. In FIG. 5B, the back electrode layer 16, absorber layer 151 and absorber layer 152 are formed on a panel of the thin film solar cell 1 and proximate to the cell anode 11. In FIG. 5C, a back electrode layer 16 is formed on an internal side on both left and right edges of the panel of the thin film solar cell 1, and each of the absorber layer 15 (151, 152) and the front electrode layer 142 are extended to a surface of the substrate 13 to produce a second isolation groove 18. The second isolation groove 18 is concavely formed on the front electrode layer 142 of the substrate 13 and filled with an insulative material 181. With the insulative material 181 of the second isolation groove 18, the front electrode layer 142 is electrically isolated by the second isolation groove 18. The second isolation groove 18 is formed after the front electrode layer 142 is formed on the substrate 13, and the front electrode layer 142 is patterned. When the absorber layer 151 is formed on a surface of the front electrode layer 142, the material of the absorber layer 151 is filled into the second isolation groove 18 to form the insulative material 181. As to the non-electrically isolated area, the back electrode layer 16 or the metal layer 161 of the back electrode layer 16 is used for an electric conduction as shown in FIG. 5D.

With reference to FIG. 5E for a schematic view of a path of passing a current of a double-deck front electrode layer of a thin film solar cell from a cell cathode to a cell anode of the solar cell in accordance with the present invention, an electron flow is produced after the absorber layers 151, 152 receive light illumination, and the cell cathode 12 (as indicated by “−” in the figure), the cell anode 11 (as indicated by “+” in the figure) and the cable junction box 23 are coupled to the outside to constitute a power supply circuit. If current is generated, the cell cathode 12 is electrically conducted through the back electrode layer 16, such that the current of the absorber layers 151, 152 flows towards the front electrode layer 142. Since the first isolation groove 17 is electrically isolated, the current can flow from the front electrode layer 142 to the conductive groove 19 only. Since the conductive groove 19 is filled with the conductive material 191, the current of the absorber layers 151, 152 is connected and flowed towards the anode (“+”), because the front electrode layer 142 is electrically isolated by the insulative material 181 of the second isolation groove 18 and the direction of the current is changed. As a result, there is no short cut. Similarly, the current is electrically conducted by the back electrode layer 16, and the current of the absorber layers 151, 152 flows towards the front electrode layer 142. By the isolation of the first isolation groove 17, the current can flow from the front electrode layer 142 to the conductive groove 19 only, and out from the cell anode (“+”), and the aforementioned components and designs constitute the thin film solar cell of the present invention.

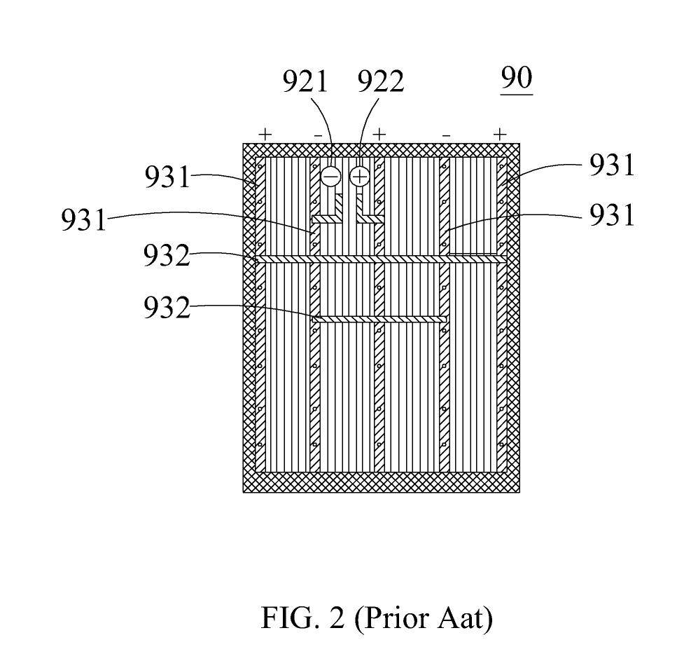

In the structure of the thin film solar cell 1 in accordance with the present invention, the first isolation groove 17 and the second isolation groove 18 are connected in series without any particular limitation of their distance apart, and a distance of 100˜800 μm is adopted in a preferred embodiment to lower the resistance and reduce the heat generating source, so as to overcome the shortcomings of the conventional thin film solar cell that adopts many long conductive ribbons (or the conductive ribbon 93 as shown in the FIG. 2). The structure of the thin film solar cell 1 of the present invention reduces the use of these conductive ribbons to lower the cost significantly.

In the thin film solar cell 1 of the present invention, the first isolation groove 17 and the second isolation groove 18 are formed by a laser cutting method or a mechanical cutting method, and the absorber layer 15 is still reserved on the first isolation groove 17, so that the effect of patterning the electrodes can be achieved without reducing the power generating area, which is one of the advantages of the present invention.

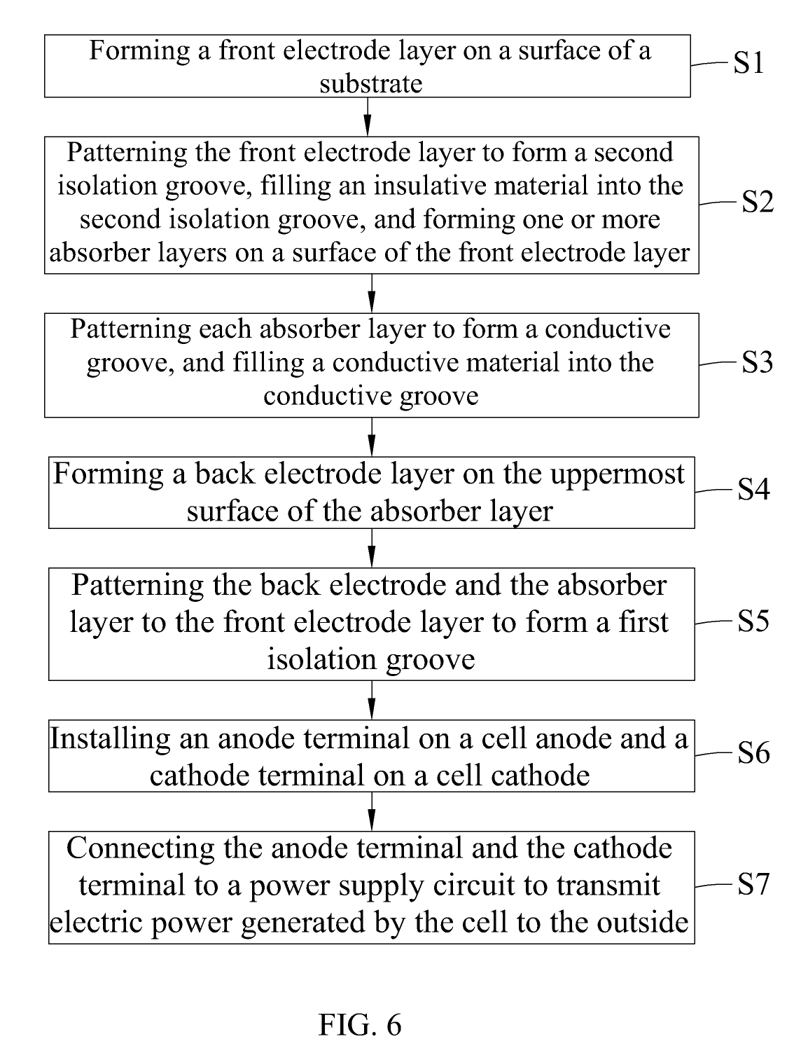

With reference to FIG. 6 for a flow chart of a method of patterning electrodes of a thin film solar cell of the present invention, a single-layer thin film solar cell 1 is used for illustrating the invention.

S1: Forming a front electrode layer 14 on a surface of a substrate 13, wherein the front electrode layer 14 is generally made of a transparent conductive oxide TCO including but not limited to tin dioxide (Sn0₂), indium tin oxide (ITO), zinc oxide (ZnO), aluminum zinc oxide (AZO), gallium zinc oxide (GZO) and indium zinc oxide (IZO);

S2: Patterning the front electrode layer 14 to form a second isolation groove 18, wherein the absorber layer 15 formed on the surface of the front electrode layer 14 is a single-layer structure or a multi-layer structure, and the single-layer structure is adopted for illustrating the present invention, and the absorber layer 15 is made of a material including but not limited to a crystalline silicon semiconductor, an amorphous silicon semiconductor, a semiconductor compound, an organic semiconductor or a sensitized dye, and when the absorber layer 15 is formed on surfaces of the front electrode layer 14 and the second isolation groove 18, the material of the absorber layer 15 is also filled into the second isolation groove 18 at the same time to act as the insulative material 181, and any other equivalent material can be used to substitute the insulative material 181;

S3: Patterning the absorber layer 15 to form a conductive groove 19, and filling a conductive material 191 into the conductive groove 19, so as to form a plurality of rectangular cells and achieve the effect of connecting them in series, wherein the conductive groove 19 can be formed by an etch, laser or mechanical cutting method, and the conductive material 191 includes but not limited to tin dioxide (Sn0₂), indium tin oxide (ITO), zinc oxide (ZnO), aluminum zinc oxide (AZO), gallium zinc oxide (GZO), indium zinc oxide (IZO) and silver paste;

S4: Forming a back electrode layer 16 on a surface of the absorber layer 15 to produce a panel of the thin film solar cell 1, wherein the back electrode layer 16 is comprised of a conductive oxide layer 162 and a metal layer 161, and the conductive oxide layer 162 is made of a material selected from the collection of tin dioxide (Sn0₂), indium tin oxide (ITO), zinc oxide (ZnO), aluminum zinc oxide (AZO), gallium zinc oxide (GZO) and indium zinc oxide (IZO), and the metal layer 161 is made of a metal selected from the collection of silver (Ag), aluminum (Al), chromium (Cr), titanium (Ti), nickel (Ni) and gold (Au);

S5: Cutting both left and right internal sides of the panel of the thin film solar cell 1 and at a position proximate to the cell anode 11 to extend the back electrode layer 16 and the absorber layer 15 to the front electrode layer 14 to form a first isolation groove 17, wherein the first isolation groove 17 is formed by an etch, laser or mechanical cutting method, and the cell anode 11 is patterned at an end of the thin film solar cell 1 (or an upper end as shown in FIG. 3A), so that current generated by the thin film solar cell 1 can be collected from the cell cathode 12 towards the cell anode 11, and during the step S5 of patterning the back electrode layer 16 and the absorber layer 15 to the front electrode layer 14 to form the first isolation groove 17, the step S3 of patterning the back electrode layer 16 and the absorber layer 15 can be performed at the same time, and after the back electrode layer 16 and the absorber layer 15 are patterned, the front electrode layer 14 is patterned to produce the second isolation groove 18, or steps S3 and S5 take place separately, and the first isolation groove 17, second isolation groove 18 and conductive groove 19 can be connected in series by patterning the thin film solar cell 1, and the positions of the cell anode 11 and cell cathode 12 can be arranged according to the conduction path of the current;

S6: Installing an anode terminal 21 on the cell anode 11 and at an appropriate position of the channel for the cable junction box 23, and installing a cathode terminal 22 on the cell cathode 12 and at a position of the channel for the cable junction box 23, wherein the anode terminal 21 and the cell anode 11 as well as the cathode terminal 22 and the cell cathode 12 can be connected by soldering or silver paste adhesion; and

S7: Connecting the anode terminal 21 and the cathode terminal 22 to a power supply circuit, such as connecting the cable junction box 23 to the anode terminal 21 and the cathode terminal 22, such that the thin film solar cell 1 can supply electric power to the outside.

As to the multi-layer structure of the absorber layer 15, the electrodes of the thin film solar cell of the present invention are patterned by the method described above:

SS1: Forming a front electrode layer 142 on a surface of a substrate 13;

SS2: Patterning the front electrode layer 142 to form a second isolation groove 18, and filling an insulative material 181 into the second isolation groove 18, and forming a first absorber layer 152 on surfaces of the front electrode layer 142 and the second isolation groove 18, and then forming a second absorber layer 151 on the absorber layer 152, and so on to produce a multi-layer power generating layer, wherein the front electrode layer 142 between the two absorber layers 151, 152 can be skip for a different cell structure;

SS3: Patterning the multi-layer absorber layers 151, 152 to form and extend each absorber layer 151, 152 to the front electrode layer 142 to produce a conductive groove 19, and filling a conductive material 191 into the conductive groove 19, so as to produce a plurality of rectangular cells and achieve the serial connection effect;

SS4: Forming a back electrode layer 16 on a surface of the uppermost absorber layer 152 of the multi-layer absorber layer to form a panel of a thin film solar cell, wherein the back electrode layer 16 is comprised of a metal layer 161 and a conductive oxide layer 162;

SS5: Cutting internal sides of both left and right edges of the panel of the thin film solar cell 1 proximate to the cell anode 11 to form the back electrode layer 16 and each of the absorber layers 151, 152 to be extended to a surface of the front electrode layer 142 to produce a first isolation groove 17;

SS5: Cutting the internal sides on both left and right edges of the panel of the thin film solar cell 1 to form the back electrode layer 16, a multi-layer absorber layer 15 (151, 152) and a front electrode layer 142 onto a surface of the substrate 13 to produce a second isolation groove 18, such that the cell anode 11 is patterned at an end of the thin film solar cell 1 (or an upper end as shown in FIG. 3A), so that the current generated by the thin film solar cell 1 can be collected from the cell cathode 12 to the cell anode 11, and when the back electrode layer 16 and each absorber layer (151, 152) are formed on the surface of the front electrode layer 142 to produce the first isolation groove 17 in the step SS5, the back electrode layer 16 and the absorber layer (151, 152) in the step SS3 can be formed at the same time, and after the back electrode layer 16 and each absorber layer (151, 152) are formed, the second isolation groove 18 is formed, or the steps SS5 and SS3 take place separately, and the positions of the first isolation groove 17, second isolation groove 18 and conductive groove 19 are arranged and designed according the to the serial connection of the thin film solar cell 1, the positions of the cell anode 11 and the cell cathode 12, and the conduction path of the current;

SS6: Installing an anode terminal 21 on the cell anode 11 and at an appropriate position of a channel for the cable junction box 23, and installing cathode terminal 22 on the cell cathode 12 and at an appropriate position of the channel for the cable junction box 23; and

SS7: Connecting the anode terminal 21 and the cathode terminal 22 to a power supply circuit, such that the cable junction box 23 can be connected to the anode terminal 21 and cathode terminal 22, and the thin film solar cell 1 can supply electric power to the outside.

What is claimed is:

1. A thin film solar cell structure, comprising a substrate, a front electrode layer, an absorber layer and a back electrode layer, stacked on one another sequentially, and further comprising a panel electrode, and the panel electrode further comprising a cell anode and a cell cathode, and a conductive channel of the cell anode and the cell cathode being formed by patterning a first isolation groove, a second isolation groove and a conductive groove, wherein:
the first isolation groove is penetrated through the back electrode layer and the absorber layer;
the second isolation groove is concavely formed on the front electrode layer and filled with an insulative material, and the insulative material of the second isolation groove is provided for electrically isolating a portion of the front electrode layer from the second isolation groove;
the conductive groove is concavely formed on the absorber layer and filled with a conductive material, and the conductive material of the conductive groove is provided for achieving an electric conduction between the front electrode layer and the back electrode layer.

2. The thin film solar cell structure of claim 1, wherein the first isolation groove and the second isolation groove are connected serially adjacent to each other.

3. The thin film solar cell structure of claim 1, wherein the insulative material of the second isolation groove is the same material used for making the absorber layer.

4. The thin film solar cell structure of claim 1, wherein the back electrode layer is formed by a transparent conductive oxide layer made of a material selected from the collection of tin dioxide, indium tin oxide, zinc oxide, aluminum zinc oxide, gallium zinc oxide and indium zinc oxide.

5. The thin film solar cell structure of claim 4, wherein the back electrode layer further comprises a metal layer made of a metal selected from the collection of silver, aluminum, chromium, titanium, nickel and gold.

6. The thin film solar cell structure of claim 1, wherein the substrate is made of a transparent material.

7. The thin film solar cell structure of claim 1, wherein the front electrode layer is made of a transparent conductive oxide selected from the collection of tin dioxide, indium tin oxide, zinc oxide, aluminum zinc oxide, gallium zinc oxide and indium zinc oxide, and the conductive material of the conductive groove is one selected from the collection of tin dioxide, indium tin oxide, zinc oxide, aluminum zinc oxide, gallium zinc oxide and indium zinc oxide, and the absorber layer is made of a material selected from the collection of a crystalline silicon semiconductor, an amorphous silicon semiconductor, a semiconductor compound, an organic semiconductor and a sensitized dye.

8. A thin film solar cell structure, comprising a substrate and a front electrode layer sequentially stacked onto a plurality of absorber layers and a back electrode layer, and further comprising a panel electrode, and the panel electrode comprising a cell anode and a cell cathode, and a conductive channel of the cell anode and the cell cathode being formed by patterning a first isolation groove, a second isolation groove and a conductive groove, wherein:
the first isolation groove is penetrated through the back electrode layer and the absorber layers;
the second isolation groove is concavely disposed proximate to the front electrode layer of the substrate and filled with an insulative material, and the insulative material of the second isolation groove is provided for electrically isolating a portion of the front electrode layer from the second isolation groove;
the conductive groove is concavely disposed on the absorber layers and filled with a conductive material, and the conductive material of the conductive groove is provided for achieving an electric conduction between the front electrode layer adjacent to the substrate and the back electrode layer.

9. The thin film solar cell structure of claim 8, wherein the first isolation groove and the second isolation groove are connected serially adjacent to each other.

10. The thin film solar cell structure of claim 8, wherein the insulative material of the second isolation groove is the same material used for making any one of the absorber layers.

11. The thin film solar cell structure of claim 8, wherein the back electrode layer is formed by stacking a transparent conductive oxide layer with a metal layer, and the transparent conductive oxide layer is made of a material selected from the collection of tin dioxide, indium tin oxide, zinc oxide, aluminum zinc oxide, gallium zinc oxide and indium zinc oxide, and the metal layer is made of a metal selected from the collection of silver, aluminum, chromium, titanium, nickel and gold.

12. The thin film solar cell structure of claim 6, wherein the front electrode layer is made of a transparent conductive oxide selected from the collection of tin dioxide, indium tin oxide, zinc oxide, aluminum zinc oxide, gallium zinc oxide and indium zinc oxide, and the conductive material of the conductive groove is one selected from the collection of tin dioxide, indium tin oxide, zinc oxide, aluminum zinc oxide, gallium zinc oxide and indium zinc oxide, and the absorber layer is made of a material selected from the collection of a crystalline silicon semiconductor, an amorphous silicon semiconductor, a semiconductor compound, an organic semiconductor and a sensitized dye.

13. A method of patterning an electrode of the thin film solar cell structure as recited in claim 1, and the method comprising the steps of:
S1: forming the front electrode layer on a surface of the substrate;
S2: patterning the front electrode layer to form the second isolation groove, filling the insulative material in the second isolation groove, and forming the absorber layer on surfaces of the front electrode layer and the second isolation groove, wherein the absorber layer is a single-layer structure;
S3: patterning the absorber layer to form the conductive groove, and filling the conductive material into the conductive groove;
S4: forming the back electrode layer on surfaces of the absorber layer and the conductive groove to produce a thin film solar cell panel; and
S5: patterning the back electrode and the absorber layer on the thin film solar cell panel to the front electrode layer to produce the first isolation groove.

14. The method of claim 13, further comprising the steps of:
S6: installing an anode terminal on a channel of the cell anode of the thin film solar cell panel, and a cathode terminal on a channel of the cell cathode of the thin film solar cell panel;
S7: connecting the anode terminal and the cathode terminal to a power supply circuit, such that the thin film solar cell is able to supply electric power to the outside.

15. The method of claim 13, wherein the insulative material filled in the second isolation groove in the step S2 is the same material used for making the absorber layer, and when the absorber layer is formed on the surface of the front electrode layer, the insulative material is filled into the second isolation groove at the same time.

16. The method of claim 13, wherein the step S2, S3 or S5 uses an etch cutting method, a laser cutting method or a mechanical cutting method.

17. A method of patterning an electrode of the thin film solar cell structure as recited in claim 6, and the method comprising the steps of:
SS1: forming the front electrode layer on a surface of the substrate;
SS2: patterning the front electrode layer to form the second isolation groove, and filling the insulative material into the second isolation groove, and forming the plurality of absorber layers on surfaces of the front electrode layer and the second isolation groove;
SS3: patterning the absorber layers to form the conductive groove, and filling the conductive material into the conductive groove;
SS4: forming the back electrode layer on the uppermost surface of the absorber layers to produce a thin film solar cell panel;
SS5: patterning the back electrode and the absorber layer on the thin film solar cell panel to the front electrode layer to produce the first isolation groove.

18. The method of claim 17, further comprising the steps of:
SS6: installing an anode terminal on a channel of the cell anode of the thin film solar cell panel, and installing a cathode terminal on a channel of the cell cathode of the thin film solar cell panel;
SS7: connecting the anode terminal and the cathode terminal to a power supply circuit, such that the thin film solar cell is able to supply electric power to the outside.

19. The method of claim 17, wherein the insulative material filled into the second isolation groove in the step SS2 is the same material for making the absorber layer adjacently coupled to the front electrode layer, and when the absorber layer is formed on the surface of the front electrode layer, the insulative material is filled into the second isolation groove at the same time.

20. The method of claim 17, wherein the steps SS2, SS3 or SS5 uses an etch cutting method, a laser cutting method or a mechanical cutting method.
